(19) United States
(12) Patent Application Publication
(10) Pub. No.: US 2020/0321202 A1
(43) Pub. Date: Oct. 8, 2020

(54) SHIELD KIT FOR PROCESS CHAMBER

(71) Applicant: Applied Materials, Inc., Santa Clara, CA (US)

(72) Inventors: William R. JOHANSON, JR., Gilroy, CA (US); Alexander ERENSTEIN, San Jose, CA (US); Ilya LAVITSKY, San Francisco, CA (US); Keith A. MILLER, Mountain View, CA (US)

(21) Appl. No.: 16/829,038

(22) Filed: Mar. 25, 2020

Related U.S. Application Data
(60) Provisional application No. 62/829,450, filed on Apr. 4, 2019.

(51) Int. Cl. H01J 37/34; C23C 14/06; C23C 14/34

(52) U.S. Cl. CPC H01J 37/3488; H01L 21/67184; C23C 14/3407; C23C 14/0652

(57) ABSTRACT

A shield kit for use in a process chamber includes a body configured to be inserted into a source disposed on a top surface of the process chamber. The body includes a top plate, a pair of far plates connected to the top plate, and a pair of side plates connected to the pair of far plates. The shield kit further includes a cooling manifold disposed on an outer surface the top plate within an opening of the source, and a vacuum seal disposed on the outer surface of the top plate and configured to vacuum seal the opening of the source. At least one of the pair of side plates has a gap extending that is aligned with at least one cathode opening on a top surface of the source.

### CROSS-REFERENCE TO RELATED APPLICATIONS

This application claims benefit of U.S. provisional patent application Ser. No. 62/829,450, filed Apr. 4, 2019, which is herein incorporated by reference.

### BACKGROUND

### Field

Embodiments of the invention relate to an apparatus and, more specifically, to a cooled process kit insert to be used in a vacuum process chamber.

### Description of the Related Art

In integrated circuits (IC), thin films are deposited on micro-electronic devices such as transistors, capacitors, and resistors by a physical vapor deposition (PVD) method. In PVD, a target is negatively charged with respect to an anode at a high voltage in the range of about 100 to about 600 V, and the negatively charged electrons bombard positively charged ions from the target, generating plasma in a vacuum process chamber. Generated positively charged ions are sputtered onto a substrate such as a silicon wafer and condensed as thin films. Sputtered ions are also deposited onto inner walls of the vacuum process chamber that are negatively biased, leading to contamination and/or flaking of components of the vacuum process chamber. Generally, a shield is bolted or clipped on the inner walls of the vacuum process chamber to prevent deposition of the sputtered ions. However, typical shields have rough edges and joints, which cause particle generations flaked off from the rough edges and joints.

Furthermore, a high bias voltage applied to the target causes a large rise in a surface temperature of the shield. Typical cooling systems to remove heat from the shield are thermally floating (i.e., in-direct cooling) and do not provide sufficient cooling. When the shield undergoes thermal cycling from plasma heating and subsequent cooling while the plasma is off, a film deposited on a surface of the shield experiences thermal stress due to a mismatch in the coefficient of thermal expansion (CTE) between the film and the underlying shield material. When the thermal stress exceeds limits of adhesion, particles flake off from the shield and land on components of the vacuum process chamber, causing damage and necessitating frequent cleaning of the vacuum process chamber. Contamination of the substrate due to the particles also causes problems with the intended IC layer growth on the substrate through electrical shorts.

Therefore, there is a need for a shield to be installed inside a vacuum process chamber that prevents particle generations and thermal stress, and provides efficient cooling of the shield.

### SUMMARY

In one embodiment, a shield kit for use in a process chamber includes a body configured to be inserted into a source disposed on a top panel of the process chamber. The body includes a top plate extending in a first direction, a pair of far plates connected to the top plate, and a pair of side plates connected to the pair of far plates. The pair of far plates extend in a second direction perpendicular to the first direction, and the pair of side plates extend in the first direction. The shield kit further includes a cooling manifold disposed on an outer surface of the top plate and at least partially exposed from an opening of the source, and a vacuum seal disposed on the outer surface of the top plate and configured to vacuum seal the opening of the source. At least one of the pair of side plates has a gap extending in the first direction from the top plate, and the gap is aligned with at least one cathode opening on a top surface of the source.

In another embodiment, a process kit for use in a process chamber includes a source configured to cover a top panel of the process chamber. The source has at least one cathode opening and an opening extending in a first direction on a top surface of the source. The process kit further includes a shield kit configured to be inserted into the source. The shield kit has at least one gap extending in the first direction on a top surface of the shield kit and being aligned with the at least one cathode opening of the source. The process kit further includes a cooling manifold disposed on the top surface of the shield kit and at least partially exposed from the opening of the source, a vacuum seal disposed on the top surface of the shield kit and configured to vacuum seal the opening of the source, and a cathode assembly extending in the first direction disposed in an internal volume of the shield kit beneath the at least one cathode opening.

In another embodiment, a shield kit insertable inside a source for use in a process chamber includes a first far plate and a second far plate. The first far plate having a first top end, a first edge, and a second edge, and the second far plate having a second top end, a third edge, and a fourth edge. The shield kit further includes a top plate having a first edge connected to the first top end of the first far plate and a second edge connected to the second top end of the second far plate, a first side plate, and a second side plate. The first side plate having a first side edge connected to the first edge of the first far plate and a second side edge connected to the third edge of the second far plate, and the second side plate having a third side edge connected to the second edge of the first far plate and a fourth side edge connected to the fourth edge of the second far plate. The shield kit further includes a first joint blocker in contact with an inner surface of the first far plate at the first top end and an inner surface of the top plate at the first edge, a second joint blocker in contact with an inner surface of the second far plate at the second top end and an inner surface of the top plate at the second edge, and a cooling manifold disposed on an outer surface the top plate. The outer surface of the top plate is aligned with the first top end of the first far plate and the second top end of the second far plate. The first edge of the first far plate and the third edge of the second far plate are aligned with an outer surface of the first side plate, and the second edge of the first far plate and the fourth edge of the second far plate are aligned with an outer surface of the second side plate.

Features of the shield kit, such as a cooling manifold, provide direct cooling of the shield kit, and thus provide efficient cooling of a source disposed in a processing chamber. Other features of the shield kit, such as smoothed corners and joints, joint blockers, and torturous paths, prevent redeposition of sputtered ions onto undesired portions of the processing chamber, and thus the ions do not redeposit and cause breakdowns of other components in the processing chamber, which reduces cleaning and other ownership costs.

### BRIEF DESCRIPTION OF THE DRAWINGS

So that the manner in which the above-recited features of the present disclosure can be understood in detail, a more particular description of the embodiments, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a processing platform, according to one embodiment

FIG. 2A illustrates an isometric top side view of a processing chamber, according to one embodiment.

FIG. 2B illustrates an isometric top side view of a chamber body, according to one embodiment.

FIG. 2C illustrates a schematic side view of the processing chamber of FIG. 1B, according to one embodiment.

FIGS. 3A, 3B, and 3C are a top perspective view and bottom perspective views of a source having a shield kit according to a first embodiment installed therein.

FIGS. 4A, 4B, and 4C are top views of a shield kit according to the first embodiment.

FIGS. 5A, 5B, and 5C are perspective views of a top assembly portion of a shield kit according to the first embodiment.

FIG. 6 is a perspective view of a corner assembly portion of a shield kit according to the first embodiment.

FIG. 7A is a partial cross-sectional view of a shield kit according to the first embodiment. FIG. 7B is an exploded view of a torturous path according to the first embodiment.

FIGS. 8A and 8B are a top view and a bottom view of a shield kit according to a second embodiment.

FIGS. 9A and 9B are a top view and a bottom view of a shield kit according to a third embodiment

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure provided herein include a shield kit that protects inner surfaces of a source disposed on a processing chamber and components of the source from redeposition. The shield kit has smooth inner surfaces that prevent particle generations thereon. The shield kit is assembled outside of the processing chamber and can be inserted into and removed from the processing chamber, without increasing a chamber downtime. The shield kit also has a direct cooling manifold that removes heat generated from cathode assemblies installed inside the shield kit. The cooling manifold is driven outside of a process volume of the processing chamber, and thus water is isolated from the process volume of the processing chamber.

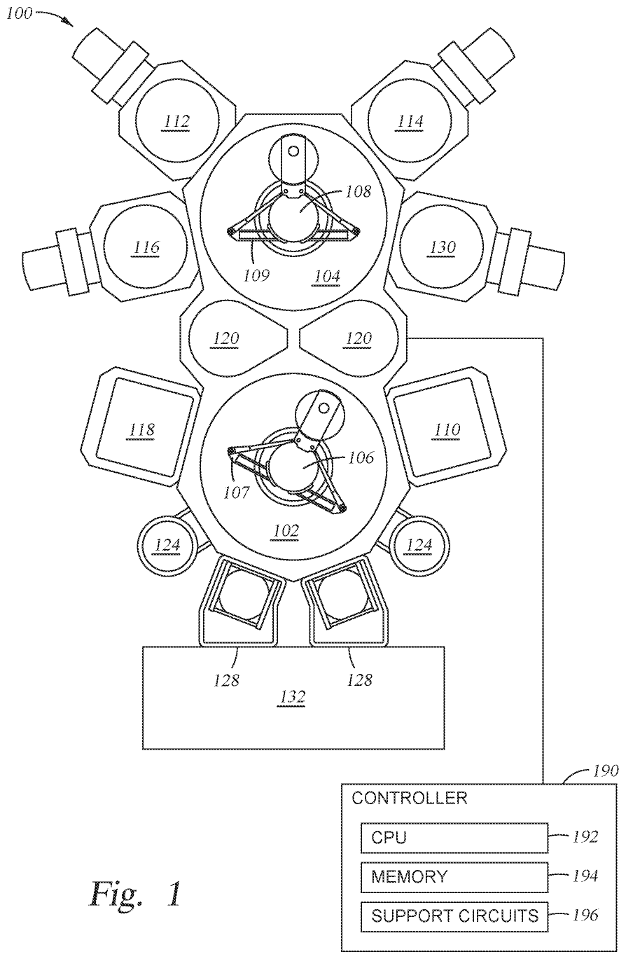

FIG. 1 illustrates a schematic top view of a processing platform 100, according to one embodiment. As shown, the processing platform 100 includes two transfer chambers 102, 104, transfer robots 106, 108 positioned in the transfer chambers 102, 104, respectively, and processing chambers 110, 112, 114, 116, 118, 130 disposed on the two transfer chambers 102, 104. The first and second transfer chambers 102, 104 are central vacuum chambers that interface with adjacent processing chambers 110, 112, 114, 116, 118, 130. The first transfer chamber 102 and the second transfer chamber 104 are separated by pass-through chambers 120, which can include cooldown or pre-heating chambers. The pass-through chambers 120 also can be pumped down or ventilated during substrate handling when the first transfer chamber 102 and the second transfer chamber 104 operate at different pressures. For example, the first transfer chamber 102 can operate between about 100 mTorr and about 5 Torr, such as about 40 mTorr, and the second transfer chamber 104 can operate between about 1×10⁻⁹ Torr and about 1×10⁻¹⁰.

The first transfer chamber 102 is coupled with two degas chambers 124, two load lock chambers 128, chemical vapor deposition (CVD) or rapid thermal processing (RTP) chambers 110, 118, and the pass-through chamber 120. Substrates (not shown) are loaded into the processing platform 100 through load lock chambers 128. For example, a factory interface module 132, if present, would be responsible for receiving one or more substrates, e.g., wafers, cassettes of wafers, or enclosed pods of wafers, from either a human operator or an automated substrate handling system. The factory interface module 132 can open the cassettes or pods of substrates, if applicable, and move the substrates to and from the load lock chambers 128. The processing chambers 110, 112, 114, 116, 118, 130 receive the substrates from the transfer chambers 102, 104, process the substrates, and allow the substrates to be transferred back into the transfer chambers 102, 104.

Each of the processing chambers 110, 112, 114, 116, 118, 130 is isolated from the transfer chambers 102, 104 by an isolation valve which allows the processing chamber to operate at a different level of vacuum than the transfer chambers 102, 104 and prevents any gases being used in the processing chamber from being introduced into the transfer chambers 102, 104. The load lock chambers 128 are also isolated from the transfer chambers 102, 104 with isolation valves. Each load lock chamber 128 has a door which opens to the outside environment, e.g., opens to the factory interface module 132. In normal operation, a cassette loaded with substrates is placed into the load lock chamber 128 through the door from the factory interface module 132, and the door is closed. The load lock chamber 128 is then evacuated to the same pressure as the transfer chamber 102, and the isolation valve between the load lock chamber 128 and the transfer chamber 102 is opened. The transfer robot 106 in the transfer chamber 102 is moved into position and one substrate is removed from the load lock chamber 128. The load lock chamber 128 is preferably equipped with an elevator mechanism so as one substrate is removed from the cassette, the elevator moves the stack of substrates in the cassette to position another substrate in the transfer plane so that it can be positioned by the transfer robot 106.

The transfer robot 106 in the transfer chamber 102 then rotates with the substrate so that the substrate is aligned with a processing chamber position. The processing chamber is flushed of any toxic gases, brought to the same pressure level as the transfer chamber, and the isolation valve is opened. The transfer robot 106 then moves the substrate into the processing chamber where it is removed from the transfer robot 106. The transfer robot 106 is then retracted from the processing chamber and the isolation valve is closed. The processing chamber then goes through a series of operations to execute a specified process on the substrate. When complete, the processing chamber is brought back to the same environment as the transfer chamber 102 and the isolation valve is opened. The transfer robot 106 removes the substrate from the processing chamber and then either moves it to another processing chamber for another operation or replaces it in the load lock chamber 128 to be removed from the processing platform 100 when the entire cassette of substrates has been processed.

The transfer robots 106, 108 include robot arms 107, 109, respectively, that support and move the substrate between different processing chambers. The transfer robot 106 moves the substrate between the degas chambers 124 and the processing chambers 110, 118 for deposition of a material thereon.

The second transfer chamber 104 is coupled to a cluster of processing chambers 112, 114, 116, and 130. The processing chambers 112 and 116 are chemical vapor deposition (CVD) chambers for depositing materials, such as tungsten (W), as desired by the operator, according to one embodiment. An example of a suitable CVD chamber includes W×Z™ chambers, commercially available from Applied Materials, Inc., located in Santa Clara, Calif. The CVD chambers are preferably adapted to deposit materials by atomic layer deposition (ALD) techniques as well as by conventional CVD techniques. The processing chambers 114 and 130 can be Rapid Thermal Annealing (RTA) chambers, or Rapid Thermal Process (RTP) chambers, that can anneal substrates at vacuum or near vacuum pressures. An example of an RTA chamber 114 is a RADIANCE™ chamber, commercially available from Applied Materials, Inc., Santa Clara, Calif. Alternatively, the processing chambers 114, 130 can be W×Z™ deposition chambers capable of performing high temperature CVD deposition, annealing processes, or in situ deposition and annealing processes. The PVD-processed substrates are moved from the first transfer chamber 102 into the second transfer chamber 104 via the pass-through chambers 120. Thereafter, the transfer robot 108 moves the substrates between one or more of the processing chambers 112, 114, 116, 130 for material deposition and annealing as required for processing.

The second transfer chamber 104 is coupled to a cluster of processing chambers 112, 114, 116, and 130. The processing chambers 112, 114,116, and 130 are physical vapor deposition (PVD) chambers for depositing materials, according to one embodiment. The CVD-processed substrates are moved from the first transfer chamber 102 into the second transfer chamber 104 via the pass-through chambers 120. Thereafter, the transfer robot 108 moves the substrates between one or more of the processing chambers 112, 114, 116, 130 for material deposition and annealing as required for processing.

RTA chambers (not shown) can also be disposed on the first transfer chamber 102 of the processing platform 100 to provide post deposition annealing processes prior to substrate removal from the processing platform 100 or transfer to the second transfer chamber 104.

While not shown, a plurality of vacuum pumps is disposed in fluid communication with each transfer chamber and each of the processing chambers to independently regulate pressures in the respective chambers. The pumps can establish a vacuum gradient of increasing pressure across the apparatus from the load lock chamber to the processing chambers.

Alternatively or in addition, a plasma etch chamber, such as a Decoupled Plasma Source chamber (DPS™ chamber) manufactured by Applied Materials, Inc., of Santa Clara, Calif., can be coupled to the processing platform 100 or in a separate processing system for etching the substrate surface to remove unreacted metal after PVD metal deposition and/or annealing of the deposited metal. For example, in forming cobalt silicide from cobalt and silicon material by an annealing process, the etch chamber can be used to remove unreacted cobalt material from the substrate surface.

Other etch processes and apparatus, such as a wet etch chamber, can be used in conjunction with the process and apparatus described herein.

A controller 190, such as a programmable computer, is connected to the processing platform 100 to control the movement of the transfer robots 106, 108 and the motion of the substrate between the various processing chambers 110, 112, 114, 116, 118, 130, and the two transfer chambers 102, 104. The controller 190 can include a central processing unit (CPU) 192, a memory 194, and support circuits 196, e.g., input/output circuitry, power supplies, clock circuits, cache, and the like. The memory 194 is connected to the CPU 192. The memory 194 is a non-transitory computable readable medium, and can be one or more readily available memory such as random access memory (RAM), read only memory (ROM), floppy disk, hard disk, or other form of digital storage. In addition, although illustrated as a single computer, the controller 190 could be a distributed system, e.g., including multiple independently operating processors and memories. This architecture is adaptable to various embodiments of the processing platform 100 based on programming of the controller 190 to control the order and timing of the movement of the substrate to and from the chambers. In addition, the controller 190 also controls various process variables in each of the processing chambers 110, 112, 114, 116, 118, 130 and transfer chambers 102, 104, such as temperature, pressure and the like.

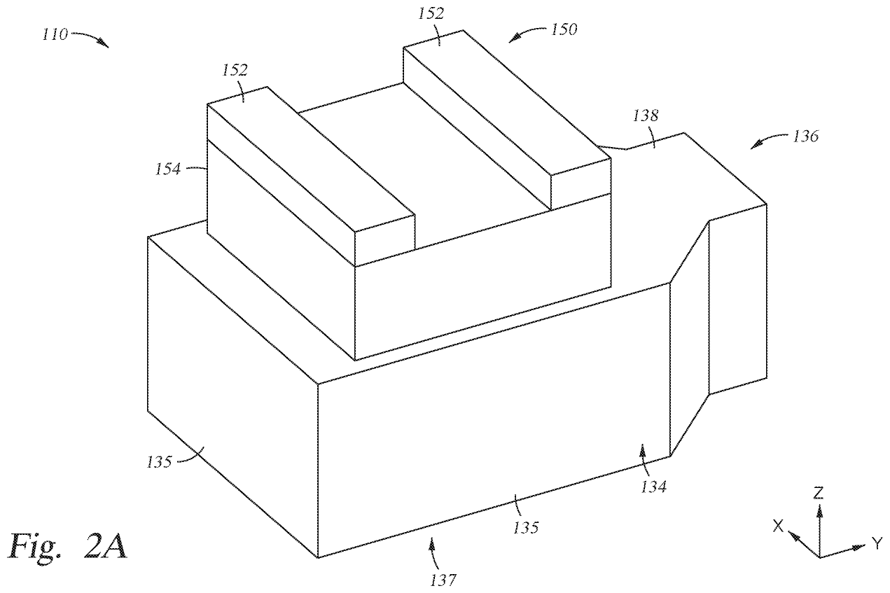

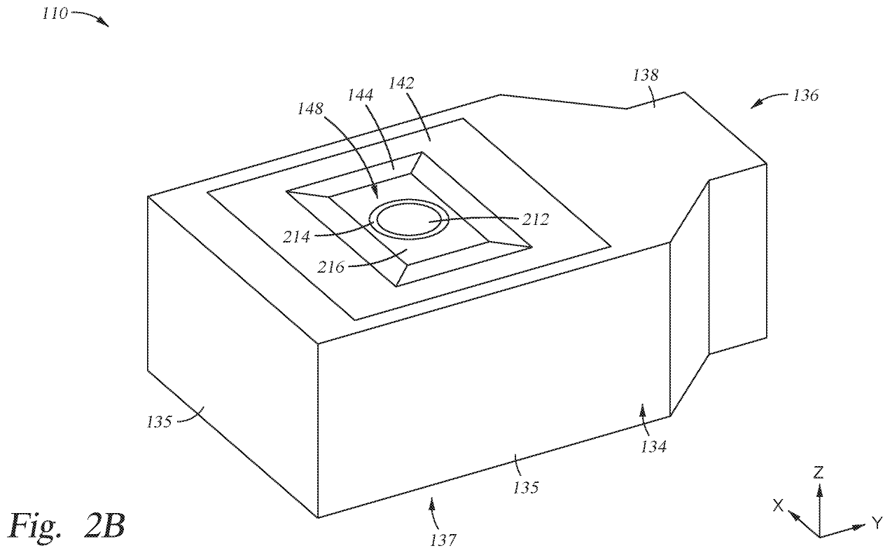

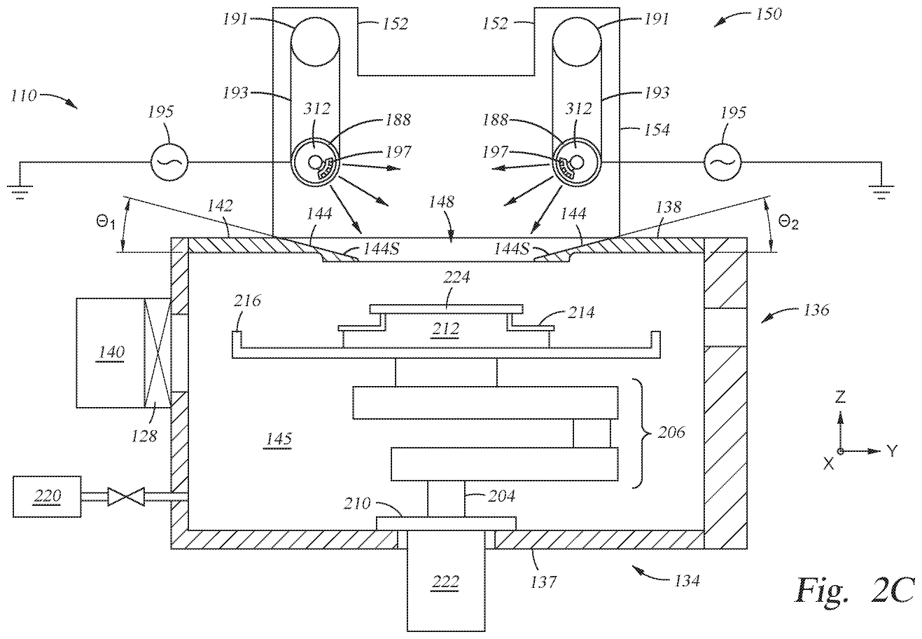

FIG. 2A illustrates an isometric top side view of processing chamber 110, according to one embodiment. As shown, processing chamber 110 includes a source assembly 150 and a chamber body 134. The source assembly 150 is separable from the chamber body 134. The source assembly 150 can be removed from the chamber body 134, in order to access an aperture 148 (FIG. 2B). The source assembly 150 is secured to the chamber body 134 during operation of the processing chamber 110.

FIG. 2B illustrates an isometric top side view of the chamber body 134, according to one embodiment. As shown, the chamber body 134 includes a top chamber surface 138 and a slot 136. The top chamber surface 138 includes a top panel 142 having a sloped portion 144. An aperture 148 is surrounded by the sloped portion 144. In some embodiments, the top panel 142 is separable, allowing for easier replacement, instead of needing to clean the top panel 142 while still installed in the chamber body 134.

The aperture 148 is rectangular, according to one embodiment. The aperture 148 is hourglass shaped, according to another embodiment. The top panel 142 can be swapped out for different deposition methods, with the shape of the aperture 148, the size of the aperture 148, and the angles θ₁ and θ₂ (shown in FIG. 2C) of the sloped portion 144 varied with the desired deposition process. The temperature of the top panel can be controlled from about −20° C. to about 400° C. In one embodiment, the top chamber surface 138 includes aluminum (Al), and the water cooling prevents overheating of the top chamber surface 138 and minimizes pealing and flaking of deposition material.

The chamber body 134 contains an interior volume 145 (shown in FIG. 2C) that is at least partially bounded by the top chamber surface 138, chamber walls 135, and chamber bottom 137 of the chamber body 134. The slot 136 is disposed in the side of the chamber body 134, which allows for motion of a substrate into and out of the chamber body.

FIG. 2C illustrates a schematic side view of the processing chamber 110 of FIG. 2A, according to one embodiment. As shown, source assembly 150 includes a plurality of pulley guards 152, a plurality of pulleys 191, a plurality of belts 193, a source 154 enclosing a plurality of cathode assemblies 312, each including a target 188 and a target magnet 197, and a target power source 195. The material of the targets 188 includes a metal or a semiconductor. The material of the targets 188 includes titanium (Ti), silicon (Si), copper (Cu), aluminum (Al), tantalum (Ta), cobalt (Co), or dielectric materials. The targets 188 include the plurality of target magnets 197. The plurality of target magnets 197 each has fixed strength that can be different among the plurality of target magnets 197. In some embodiments, the plurality of target magnets 197 includes electromagnets. The target power sources 195 can be located in the source assembly 150, or outside the source assembly 150. The powered target magnets 197 cause sputtering of the targets 188 through an electromagnetic interaction, which deposits material from the targets on a substrate through the aperture 148 below.

The targets 188 are cylindrical, according to some embodiments. The targets 188 can be connected to the pulleys 191 by the belts 193, and the targets can be rotated during sputtering, according to one embodiment. The rotation of the targets 188 results in a more even erosion of the material from the targets onto a substrate positioned below. The pulleys 191 are protected from the outside environment by the pulley guards 152. The pulley guards 152 protect the pulleys 191 from damage during assembly, disassembly, or functioning of the processing chamber 110.

In some embodiments, a process gas is flowed during the sputtering process, and at least some of the process gas reacts with the sputtered material. The process gas may include argon (Ar), neon (Ne), or krypton (Kr), to maintain the desired pressure of the process gas. The process gas may include reactive gas such as nitrogen gas (N₂). In some embodiments, the material of the targets 188 includes silicon (Si), and the material deposited on the substrate includes silicon nitride (SiN). In some embodiments, the material of the targets 188 includes Ti, and the material deposited on the substrate includes titanium nitride (TiN).

The top surfaces 144S of the sloped portion 144 are at angles θ₁ and θ₂ to the X-direction and the Y-direction, wherein the X-direction and Y-direction are substantially parallel to the top chamber surface 138. The angles θ₁ and θ₂ range from about greater than 0° to about less than 90°, such as about 15° to about 35°, according to one embodiment. In some embodiments, the angles θ₁ and θ₂ are not equal.

As shown, the chamber body 134 houses a substrate support 200. The substrate support 200 includes a robot actuator 222, a mounting flange 210 disposed on the chamber bottom 137 of the chamber body 134, a robot arm set 206, and a halo 216. The substrate support 200 is disposed in the interior volume 145 of the chamber body 134. The robot actuator 222 is configured to move the robot arm set 206. The robot arm set 206 supports the halo 216.

As shown, on the halo 216, a substrate holder 212 and a deposition ring 214 are disposed. The substrate holder 212 includes a ceramic material, stainless steel, or other suitable material. The deposition ring 214 surrounds a substrate 224 disposed on the substrate holder 212. The deposition ring 214 includes a dielectric material. The halo 216 at least partially surrounds the deposition ring 214. The halo 216 includes a metal, such as titanium (Ti) or stainless steel. The halo 216 includes a pattern or stiffening elements that reduces strain in the halo 216. The pattern or stiffening elements can be indentations in the halo, such as an X or cross shape. The halo 216 prevents unwanted deposition of material on the other components of the substrate support 200 below. A substrate can be placed on the substrate holder 212 and be transferred in and out of the interior volume 145 of the chamber body 134 via the slot 136.

The substrate support 200 includes a heater (not shown), and the heater heats the substrate support 200 and the substrate disposed on the substrate support 200 to temperatures between about 20° C. and about 400° C., according to one embodiment. The substrate support 200 includes a cooling apparatus (not shown), for example, a cooling manifold, and the cooling apparatus controls the temperature of the support structure and the substrate disposed on the support structure to temperatures between about −20° C. and about 100° C., according to one embodiment. The substrate support 200 includes an electrostatic chuck (ESC) (not shown), and the substrate is chucked to the ESC, according to one embodiment. The ESC provides an applied voltage to the substrate disposed on the substrate support 200, according to one embodiment.

As shown, the chamber body 134 is connected to a cryogenic pump 140 that pumps water and other gases from the chamber body 134 via a gate valve 218, and a vacuum pump 220.

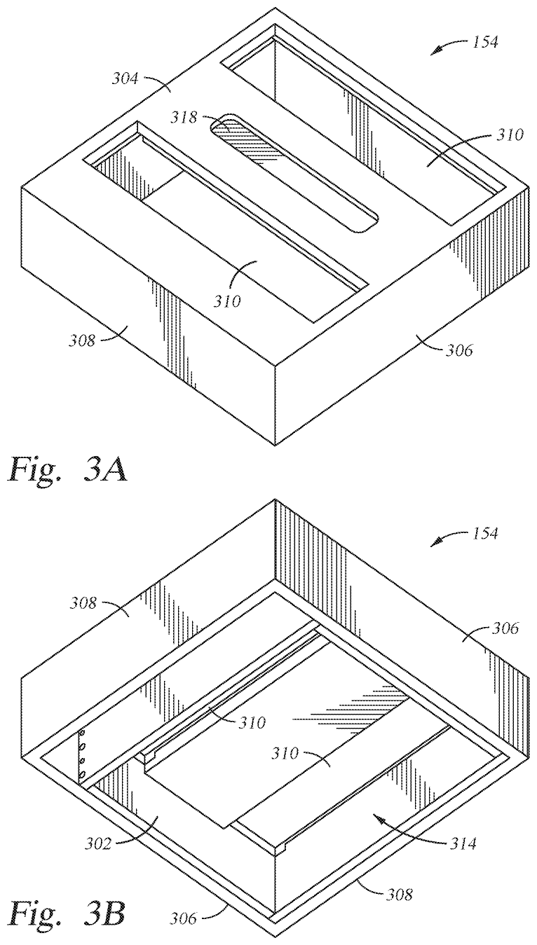

FIGS. 3A, 3B, and 3C are a top perspective view and bottom perspective views of the source 154 having a shield kit (also referred to as a “water cooled process kit insert” or a “shield liner”) 302 according to a first embodiment installed therein. The source 154 has a top face 304, first side faces 306, and second side faces 308. The source 154 is separable from the top chamber surface 138. When the source 154 is installed onto the top chamber surface 138, the source 154 covers the aperture 148. The first side faces 306 and the second side faces 308 are secured to the top chamber surface 138 with an alignment/engagement mechanism (not shown).

In some embodiments, the top face 304 has a plurality of cathode openings 310 (two openings are shown). As shown in FIG. 3C, the plurality of cathode assemblies 312 are inserted into an internal volume 314 of the shield kit 302 through the plurality of openings (also referred to as “cathode openings”) 310. The material of the targets 188 is sputtered throughout the internal volume 314 and towards the aperture 148 and onto a substrate 316 disposed on the substrate holder 212 (shown in FIG. 2C). The top face 304 of the source 154 enables water or coolant flowing to the shield kit 302.

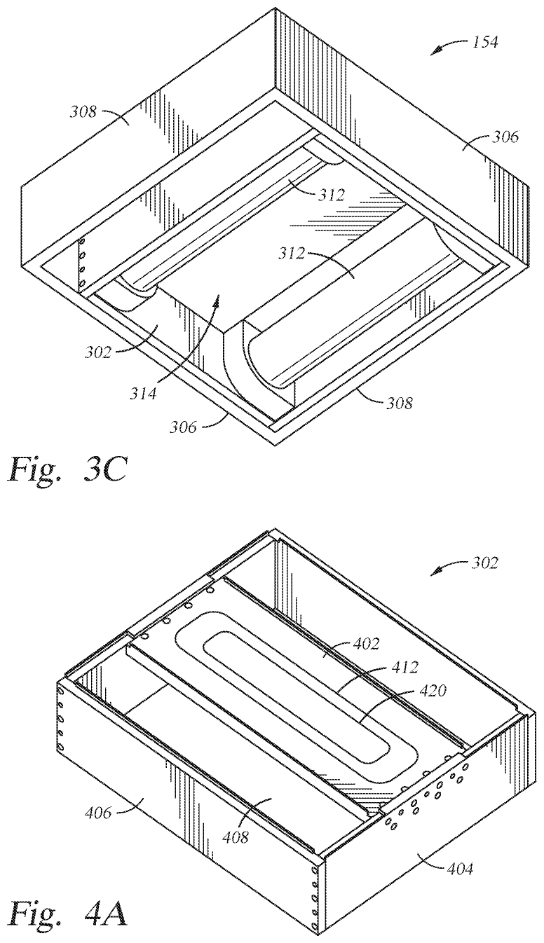

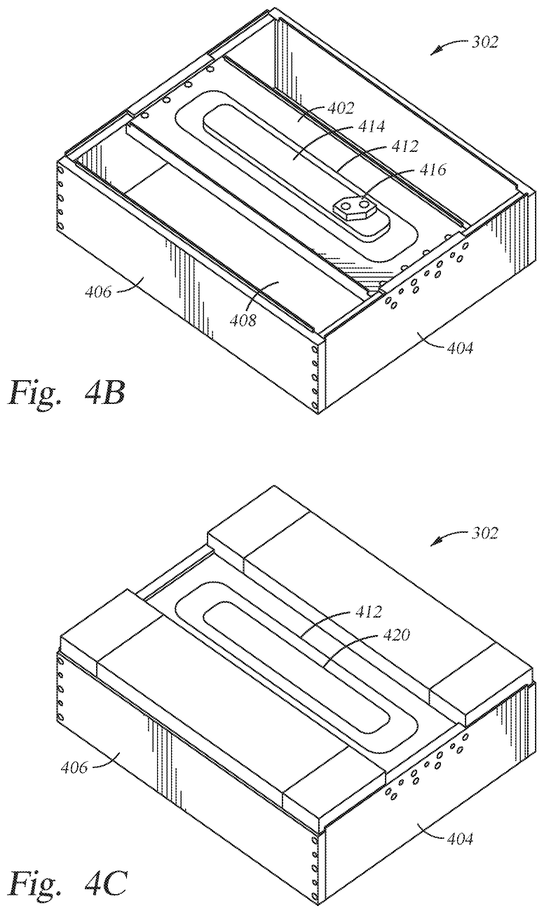

FIGS. 4A, 4B, and 4C are top views of the shield kit 302 removed from the source 154. The shield kit 302 is a body including a top plate 402, far plates 404, and side plates 406. A plurality of gaps (also referred to as “openings”) 408 between the top plate 402 and the side plates 406 (two gaps are shown) are aligned with the plurality of cathode openings 310 (shown FIGS. 3A and 3B) of the source 154, when the shield kit 302 is installed inside the source 154. The plurality of gaps 408 and the plurality of cathode openings 310 are substantially the same shapes and sizes.

The top plate 402 is positioned beneath the top face 304 of the source 154 between an adjacent pair of the plurality of cathode openings 310. On the top plate 402, a vacuum seal 412 that contours the opening 318 of the source 154 to seal between the top plate 402 of the shield kit 302 and the top face 304 of the source 154. Further on the top plate 402, a cooling manifold 414 (shown in FIG. 4B) that is connectable via connection holes 416 to a cooling water supply (not shown) is installed. The cooling manifold 414 is at least partially exposed from the source 154 through the opening 318 of the source 154, facing atmosphere and is sealed with a water seal 420. Thus, even if there is a water leak from the cooling manifold 414, the leaked water is prevented from entering into the internal volume 314 of the shield kit 302. The cooling manifold 414 provides direct cooling of the top plate 402 heated by the plurality of cathode assemblies 312. The side plates 406 are moderately heated by the plurality of cathode assemblies 312. The heat on the side plates 406 is removed by thermally conducting to the top plate 402 via the far plates 404.

In the first embodiment, the shield kit 302 is a multi-piece kit. That is, the top plate 402, the far plates 404, and the side plates 406 are separate pieces. The top plate 402, the far plates 404, and the side plates 406 may be made of aluminum plates having thickness of about ½ inch. Due to high thermal conductivity of aluminum, the heat generated on the shield kit 302 can be effectively removed. The top plate 402 and the side plates 406 shield the material of the targets 188 from depositing onto inner surfaces of the source 154. Heating of the far plates 404 by the cathode assemblies 312 and deposition of the materials from the targets 188 are minimal. However, the far plates 404 provide mechanical stability for assembly of the shield kit 302.

The shield kit 302 is assembled outside of the processing chamber 110 and can be inserted into and removed from the processing chamber 110 as assembled and placed onto the top chamber surface 138 for replacing the shield kit 302, without increasing a chamber downtime.

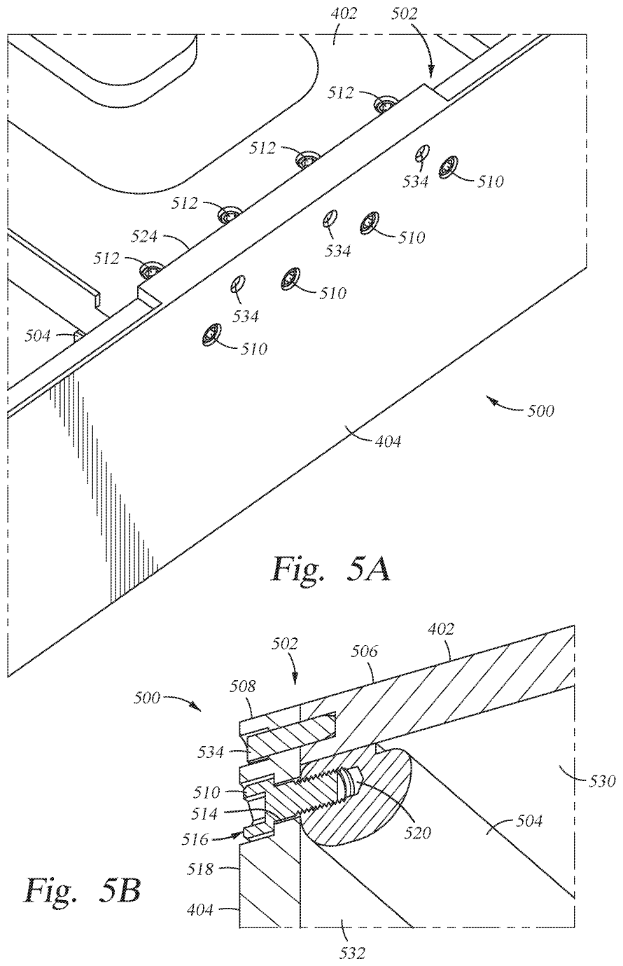

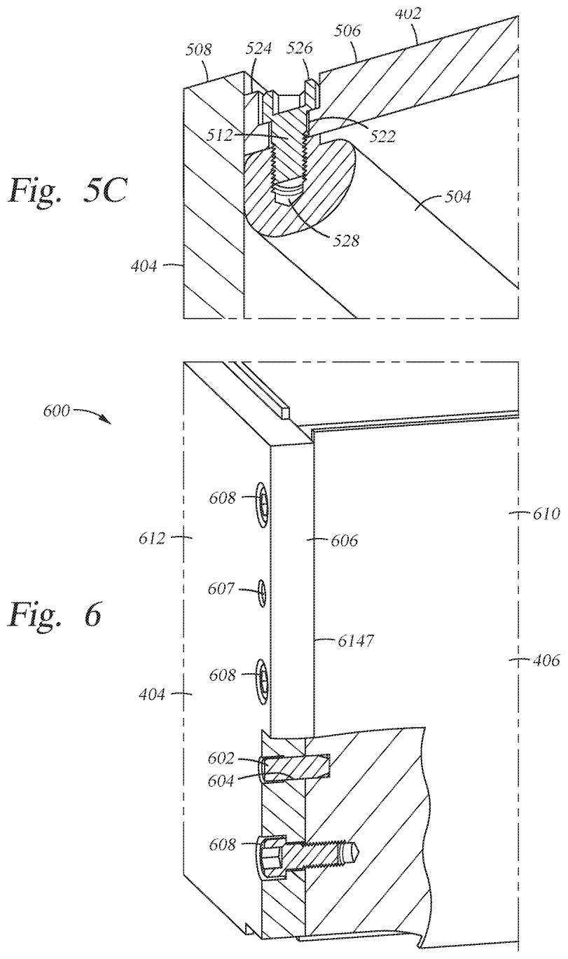

FIGS. 5A, 5B, and 5C are perspective views of a top assembly portion 500 of the shield kit 302, including a joint 502 between the top plate 402 and the far plate 404 and a joint blocker 504 disposed at the joint 502. The joint blocker 504 is made of wear and galling resistant alloy such as NITRONIC® 60, or a similar material.

An outer surface 506 of the top plate 402 is aligned and planarized with a top end 508 of the far plate 404 by pins 534 inserted (e.g., press fit) from an outer surface 518 of the far plate 404 into the top plate 402. A plurality of fasteners 510 and 512 are inserted into the joint blocker 504 through a plurality of slots 514 formed near the top end 508 and the far plate 404. As shown in FIG. 5B, one end 516 of each fastener 510 is aligned with the outer surface 518 of the far plate 404, and the other end 520 of each fastener 510 is surrounded by the joint blocker 504. The plurality of fasteners 512 are inserted into the joint blocker 504 through a plurality of slots 522 formed on an edge 524 of the top plate 402 adjacent to the far plate 404. As shown in FIG. 5C, one end 526 of each fastener 512 is aligned with the outer surface 506 of the top plate 402 and the other end 528 of each fastener 512 is surrounded by the joint blocker 504.

The joint blocker 504 at the joint 502 is in contact with an inner surface 530 of the top plate 402 and an inner surface 532 of the far plate 404. Thus, deposition of the material of the targets 188 onto and particle generations from rough edges and joints are prevented. In some embodiments, the inner surface 530 of the top plate 402 and the inner surface 532 of the far plate 404 can be texturized, grit blasted, arc sprayed, or prepared in other similar ways, which improves the adhesion of deposition of the material of the targets 188.

FIG. 6 is a perspective view of a corner assembly portion 600 of the shield kit 302, including one of the far plates 404 and one of the side plates 406. A plurality of pins 602 (two are shown) are inserted (e.g., press fit) into the side plate 406 through a plurality of slots 604 formed on an edge 606 of the far plate 404 for alignment and planarization such that the edge 606 of the far plate 404 is aligned with an outer surface 610 of the side plate 406. The side plate 406 is further secured by screws 608 inserted directly from an outer surface 612 of the far plate 404 into a side edge 614 the side plate 406.

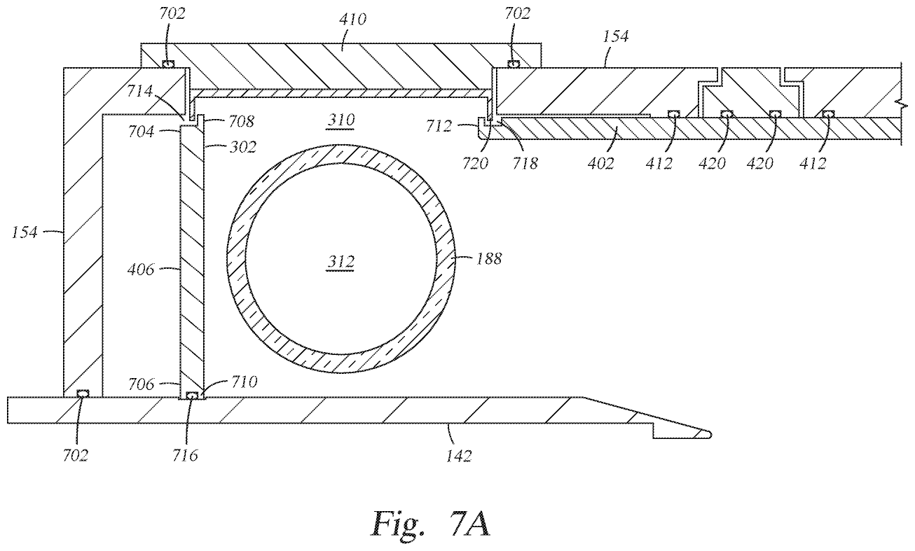

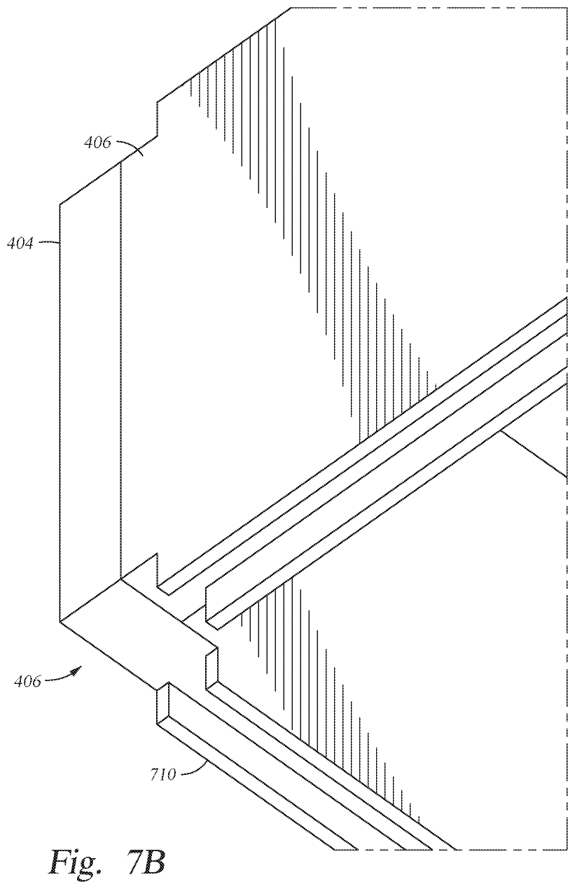

FIG. 7A is a partial cross-sectional view of the shield kit 302 installed inside the source 154 on the top panel 142. The plurality of pulleys 191 and the pulley guards 152 of the source assembly 150 (shown in FIG. 2C) are secured on a plurality of mounting plates 410. The plurality of cathode assemblies 312 is installed inside the internal volume 314 of the shield kit 302 (shown in FIG. 3C). The plurality of cathode openings 310 of the source 154 is vacuum sealed with the mounting plate seal 702 beneath the mounting plate 410. At a top end 704 and a bottom end 706 of the side plate 406, and on an edge of the top plate 402 adjacent to one of the cathode openings 310, torturous paths 708, 710, and 712 are formed. FIG. 7B is an exploded view of the torturous path 710 at the bottom end 706 of the side plate 406. The torturous paths 708, 710, and 712 respectively prevent deposition of material from the target 188 on inner surfaces of the source 154 via a gap 714 between the top end 704 and the mounting plate 410, a gap 716 between the bottom end 706 and the top panel 142, and a gap 718 between the top plate 402 and the mounting plate 410. For example, the material from the target 188 may bounce at the torturous path 712 and further bounce at a tip 720 of the mounting plate seal 702. It is believed that by the time the material from the target 188 bounces twice, a negligible amount of the material is left to pass through the gap 718. Thus, with the torturous paths 708, 710, and 712, the inner surfaces of the source 154 are protected from deposition of the material from the target 188 thereon.

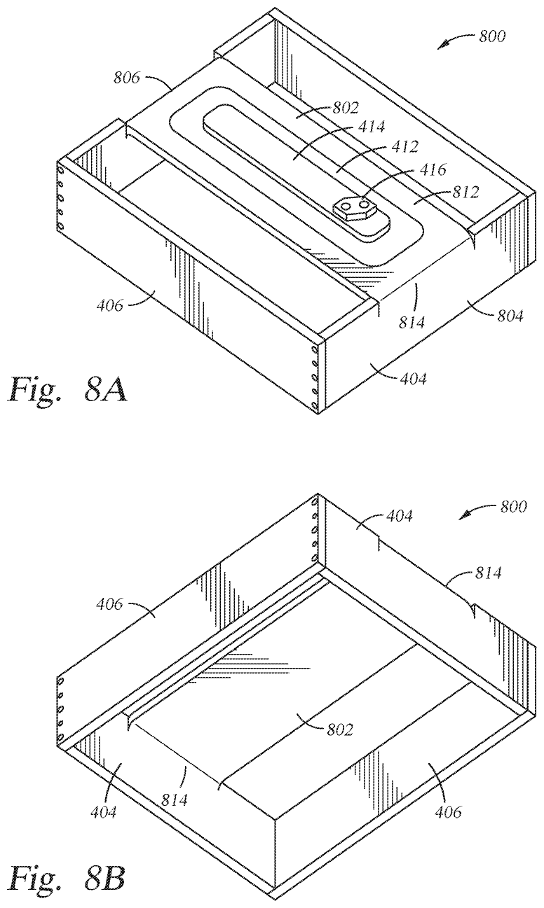

FIGS. 8A and 8B are a top view and a bottom view of a shield kit 800 according to a second embodiment. The shield kit 800 includes a center section 802 that is smoothly bent at both ends 804 and 806 to form the far plates 404. In the second embodiment, the top plate 402 and the joints 502 according to the first embodiment are replaced with the bent center section 802. The same reference numerals are used for the components that are substantially the same as those of the first embodiment, and the description of repeated components may be omitted.

Since there are no rough edges or joints interfacing a top surface 812 of the center section 802 and a side surface 814 of the center section 802, there is no need to provide the joint blocker 504 to prevent particle generations at the ends 808 and 810 of the center section 802. Furthermore, the center section 802 is made of a single piece from the top surface 812 to the side surface 814, and thus provides better heat conduction between the side surface 814 and the top surface, on which the cooling manifold 414 is disposed.

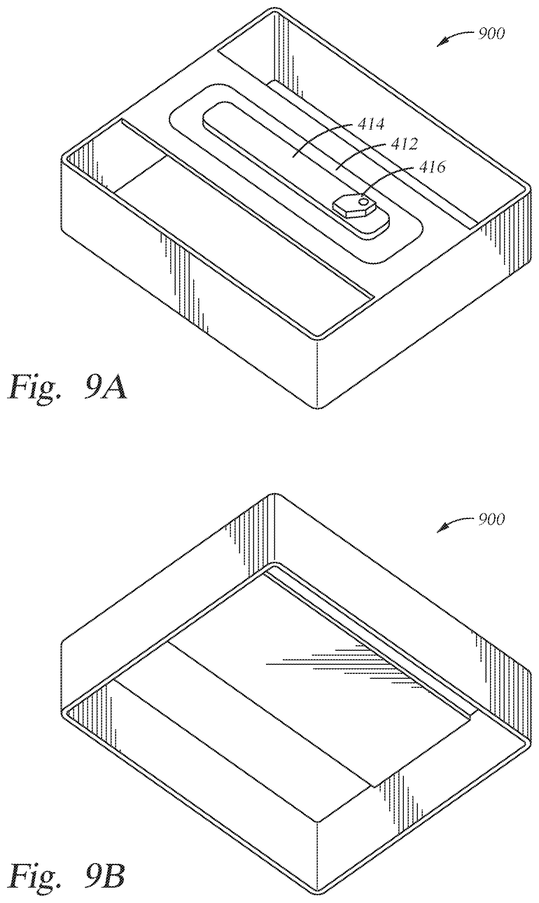

FIGS. 9A and 9B are a top view and a bottom view of a shield kit 900 according to a third embodiment. In the third embodiment, the shield kit 900 is fabricated from a single piece of material, instead of assembling separate pieces. Alternatively, the shield kit 900 is cast into a single piece. The same reference numerals are used for the components that are substantially the same as those of the first embodiment, and the description of repeated components may be omitted. Since there are no joints in the shield kit 900 there is no need to provide the joint blocker 504 to prevent particle generations inside the shield kit 900. Furthermore, the shield kit 900 is made of a single piece, and thus provides best heat conductivity.

While the foregoing is directed to implementations of the present invention, other and further implementations of the invention may be devised without departing from the basic scope thereof, and the scope thereof is determined by the claims that follow.

We claim:

1. A shield kit for use in a process chamber, comprising:
a body configured to be inserted into a source disposed on a top surface of the process chamber, the body comprising:
a top plate extending in a first direction;
a pair of far plates connected to the top plate, the pair of far plates extending in a second direction perpendicular to the first direction; and
a pair of side plates connected to the pair of far plates, the pair of side plates extending in the first direction, wherein at least one of the pair of side plates has a gap extending in the first direction from the top plate, and the gap is aligned with at least one cathode opening on a top surface of the source;
a cooling manifold disposed on an outer surface the top plate and configured for connection to coolant lines through an opening of the source; and
a vacuum seal disposed on the outer surface of the top plate to a underside of the opening of the source.

2. The shield kit according to claim 1, further comprising:
a water seal disposed on the outer surface of the top plate and configured to seal the cooling manifold.

3. The shield kit according to claim 1, wherein
each the pair of side plates comprises torturous paths at a top end and a bottom end, and
the top plate comprises torturous paths on an edge of adjacent to the at least one cathode opening.

4. The shield kit according to claim 1, wherein the body comprises aluminum.

5. The shield kit according to claim 1, further comprising:
a joint blocker on an inner surface of a joint of the top plate and each of the pair of far plates.

6. The shield kit according to claim 5, wherein the joint blocker comprises a high performance alloy material.

7. The shield kit according to claim 1, wherein the top plate and top ends of the pair of far plates are one piece that is smoothly bent at both ends.

8. The shield kit according to claim 1, wherein the body is one piece.

9. A process kit for use in a process chamber, comprising:
a source configured to cover a top surface of the process chamber, the source having at least one cathode opening and an opening extending in a first direction on a top surface of the source;
a shield kit configured to be inserted into the source, the shield kit having at least one gap extending in the first direction on a top surface of the shield kit and being aligned with the at least one cathode opening of the source;
a cooling manifold disposed on the top surface of the shield kit and at least partially exposed from the opening of the source;
a vacuum seal disposed on the top surface of the shield kit; and
a cathode assembly extending in the first direction disposed in an internal volume of the shield kit beneath the at least one cathode opening.

10. The process kit according to claim 9, further comprising:
a water seal disposed on the top surface of the shield kit and configured to seal the cooling manifold.

11. The process kit according to claim 9, wherein
each of side surfaces of the shield kit comprises torturous paths at a top end and a bottom end, the side surfaces extending in the first direction, and
the top surface of the shield kit comprises torturous paths on an edge of adjacent to the at least on cathode opening.

12. The process kit according to claim 9, wherein the shield kit comprises aluminum.

13. The process kit according to claim 9, further comprising:
a joint blocker on an inner surface of a joint of the top surface of the shield kit and each of far side surfaces of the shield kit, the far side surfaces extending in a second direction perpendicular to the first direction.

14. The process kit according to claim 13, wherein the joint blocker comprises a high performance alloy material.

15. The process kit according to claim 9, wherein the top surface of the shield kit and top ends of far side surfaces of the shield kit are one piece that is smoothly bent at both ends, the far side surfaces extending in a second direction perpendicular to the first direction.

16. The process kit according to claim 9, wherein the shield kit is one piece.

17. A shield kit insertable inside a source for use in a process chamber, comprising:
a first far plate and a second far plate, the first far plate having a first top end, a first edge, and a second edge, and the second far plate having a second top end, a third edge, and a fourth edge;
a top plate having a first edge connected to the first top end of the first far plate and a second edge connected to the second top end of the second far plate;
a first side plate and a second side plate, the first side plate having a first side edge connected to the first edge of the first far plate and a second side edge connected to the third edge of the second far plate, and the second side plate having a third side edge connected to the second edge of the first far plate and a fourth side edge connected to the fourth edge of the second far plate;
a first joint blocker in contact with an inner surface of the first far plate at the first top end and an inner surface of the top plate at the first edge;
a second joint blocker in contact with an inner surface of the second far plate at the second top end and the inner surface of the top plate at the second edge; and
a cooling manifold disposed on an outer surface the top plate, wherein
the outer surface of the top plate is aligned with the first top end of the first far plate and the second top end of the second far plate,
the first edge of the first far plate and the third edge of the second far plate are aligned with an outer surface of the first side plate, and
the second edge of the first far plate and the fourth edge of the second far plate are aligned with an outer surface of the second side plate.

18. The shield kit according to claim 17, further comprising:
a water seal disposed on the outer surface of the top plate and configured to seal the cooling manifold.

19. The shield kit according to claim 17, wherein the first and second far plates, the top plate, and the first and second side plates comprise aluminum.

20. The shield kit according to claim 17, wherein
inner surfaces of the first and second far plates and the inner surface of the top plate are textured.
